(19) United States
(12) Patent Application Publication
(10) Pub. No.: US 2005/0045486 A1
(43) Pub. Date: Mar. 3, 2005

(54) Plating method and plating solution

(76) Inventors: Tsuyoshi Sahoda, Tokyo (JP); Tsutomu Nakada, Tokyo (JP); Koji Mishima, Tokyo (JP); Ryoichi Kimizuka, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 10/885,136

(22) Filed: Jul. 7, 2004

(30) Foreign Application Priority Data
Jul. 9, 2003 (JP) 2003-194128

(51) Int. Cl. C25D 5/02; H01L 21/445

(52) U.S. Cl. 205/123; 205/291

(57) ABSTRACT

The present invention provides a plating method which can embed copper in interconnect recesses, such as vias and interconnect trenches, having an opening width or size of several tens of μm and an aspect ratio of at least 1.5. The plating method comprises: providing a substrate having interconnect recesses, whose surfaces are covered with a conductive layer, formed in a surface of the substrate; bringing the surface of the substrate into contact with a plating solution containing copper ions, an organic or inorganic acid, chloride ions, a polymeric surfactant for suppressing electrodeposition, a sulfur-containing saturated organic compound for promoting the growth of a plated film, and a nitrogen-containing polymer for flattening a surface of the plated film; and applying a voltage between the conductive layer and an anode immersed in the plating solution.

### BACKGROUND OF THE INVENTION

1. Field of the Invention

The present invention relates to a plating method for embedding copper (Cu) in interconnect recesses (circuit pattern) formed in a surface of a substrate, such as a semiconductor substrate, a printed circuit board, or a CSP (chip-size-package) substrate, or the like, and to a plating solution for use in the plating method. The plating method of the present invention is useful especially for embedding copper in interconnect recesses, having an opening width or size of not less than 1 μm and an aspect ratio of at least 1, without the formation of voids.

2. Description of the Related Art

Interconnect recesses, such as interconnect trenches and vias, having an opening width or size of several tens of μm and an aspect ratio of at least 1.5, are employed in the actual formation of interconnects, and the aspect ratio is expected to become larger in the future. There is now a demand for embedding copper, by plating, in such interconnect recesses having an opening width or size of several tens of μm and an aspect ratio of at least 1.5.

Embedding of copper has been possible in the prior art only in those interconnect recesses which have an opening size or width of several tens of μm and have an aspect ratio of at most 1. This is because if copper is embedded by plating in interconnect recesses having an aspect ratio of more than 1, an electric current concentrates in the openings of the interconnect recesses during plating, and therefore the plating rate is higher in the openings. As a consequence, the openings can be closed before the interconnect recesses is embedded with copper, resulting in the formation of large voids in copper embedded in the interconnect recesses.

### SUMMARY OF THE INVENTION

A demand therefore exists for a new plating method which can embed copper in interconnect recesses, such as vias and interconnect trenches, having an opening width or size of several tens of μm and an aspect ratio of at least 1.5. An object of the present invention is to provide such a plating method.

The present inventors have noticed that in order to embed copper by plating in interconnect recesses (vias or interconnect trenches) having an aspect ratio of at least 1, it is necessary to moderate the concentration of electric current in the openings of the interconnect recesses. As a result of studies of copper-plating solutions, it has now been found that the use as an additive of a nitrogen-containing polymer can moderate the concentration of electric current in the openings of interconnect recesses. The present invention has been accomplished based on this finding.

The plating method of the present invention comprises: providing a substrate having interconnect recesses, whose surfaces are covered with a conductive layer, formed in a surface of the substrate; bringing the surface of the substrate into contact with a plating solution containing copper ions, an organic or inorganic acid, chloride ions, a polymeric surfactant for suppressing electrodeposition, a sulfur-containing saturated organic compound for promoting the growth of a plated film, and a nitrogen-containing polymer for flattening a surface of the plated film; and applying a voltage between the conductive layer and an anode immersed in the plating solution.

The plating solution of the present invention comprises copper ions, an organic or inorganic acid, chloride ions, a polymeric surfactant for suppressing electrodeposition, a sulfur-containing saturated organic compound for promoting the growth of a plated film, and a nitrogen-containing polymer for flattening a surface of the plated film.

### BRIEF DESCRIPTION OF THE DRAWINGS

FIGS. 1A through 1C are diagrams illustrating, in a sequence of process steps, an example of the formation of copper interconnects; and

FIG. 2 is a schematic view of an electroplating apparatus useful for carrying out the plating method of the present invention.

### DETAILED DESCRIPTION OF THE PREFERRED EMBODIMENTS

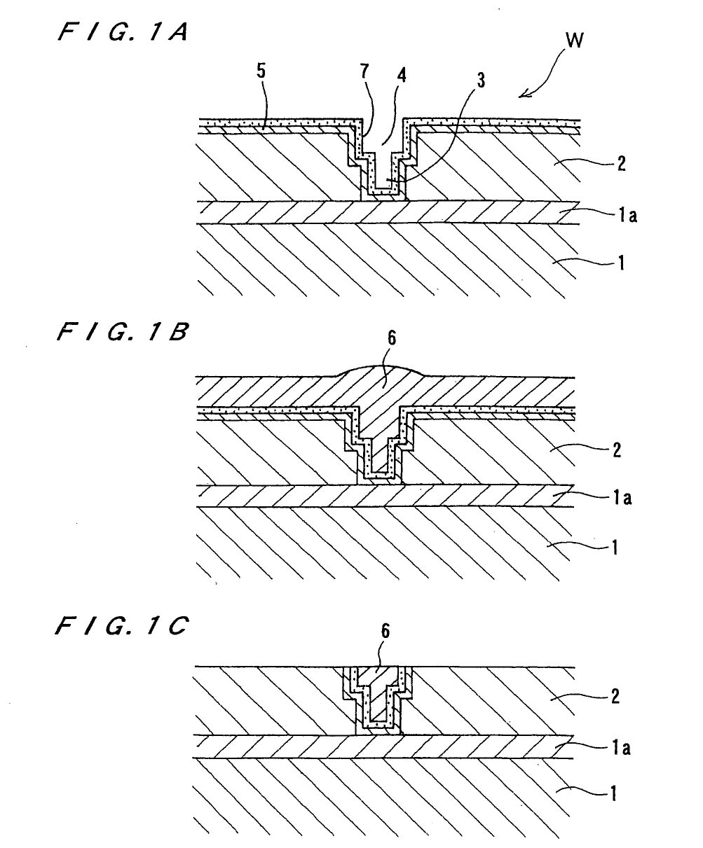

FIGS. 1A through 1C illustrate, in a sequence of process steps, an example of the production of a substrate W having copper interconnects. As shown in FIG. 1A, an insulating film 2, such as an oxide film of SiO₂ or a film of low-k material, is deposited on a conductive layer 1a in which semiconductor devices are formed and which is formed on a semiconductor base 1. Vias 3 and interconnect trenches 4, as interconnect recesses, are formed in the insulating film 2 by performing a lithography/etching technique. Thereafter, a barrier layer 5 of Ta, TaN, TiN, WN, SiTiN, COWP, or COWB, or the like is formed on an entire surface of the insulating film 2, and a seed layer 7, serving as an electric feeding layer (conductive layer) in electroplating, is formed on the barrier layer 5.

Thereafter, as shown in FIG. 1B, copper plating is carried out onto the surface of the substrate W to fill the vias 3 and the interconnect trenches 4 with copper and, at the same time, deposit a copper film 6 on the insulating film 2. Thereafter, the copper film 6, the seed layer 7 and the barrier layer 5 on the insulating film 2 are removed by chemical-mechanical polishing (CMP) so as to make surfaces of the copper film 6, filling the vias 3 and the interconnect trenches 4, substantially flush with the surface of the insulating film 2. Interconnects composed of the copper film 6 are thus formed, as shown in FIG. 1C.

Though in this embodiment a semiconductor substrate is used as a substrate, the present method is also applicable to a printed circuit board, or a CSP substrate, or the like.

Though there is no particular limitation on the interconnect trenches and vias provided as interconnect recesses in the surface of the substrate, the present invention can best offer its advantages for those interconnect recesses which have an opening width or size of several tens of μm and an aspect ratio of at least 1.5. The seed layer (conductive layer) 7 may be formed by, for example, metal (including carbon) coating using electroless plating, the so-called direct plating with carbon, palladium, etc., sputtering, vapor deposition or chemical vapor deposition (CVD).

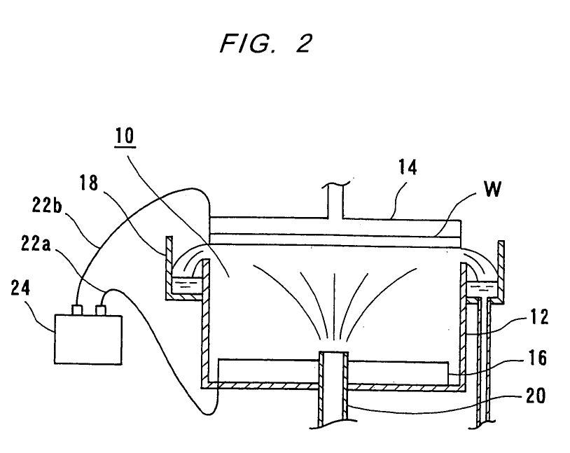

FIG. 2 schematically shows a plating apparatus useful for carrying out the plating method of the present invention. The plating apparatus includes an upwardly-open plating tank 12 for holding a plating solution 10 therein, and a vertically movable substrate holder 14 for detachably holding the substrate W with its front surface (surface to be plated) facing downwardly (face down). An anode 16 is disposed horizontally at the bottom of the plating tank 12. An overflow tank 18 is provided around the top portion of the plating tank 12. Further, a plating solution supply nozzle 20 is connected to the bottom of the plating tank 12.

In operation, the substrate W, having the seed layer 7 formed in the surface (see FIG. 1A), is held horizontally by the substrate holder 14, and is located at a position at which it closes the top opening of the plating tank 12. The plating solution 10 is supplied from the plating solution supply nozzle 20 into the plating solution tank 12 and the plating solution 10 is allowed to overflow the top end of the plating tank 12, thereby bringing the plating solution 10 into contact with the seed layer 7 on the surface of the substrate W held by the substrate holder 14, while the anode 16 is connected via a conductive wire 22a to the positive pole of a plating power source 24 and the seed layer 7 of the substrate W is connected via a conductive wire 22b to the negative pole of the plating power source 24. As necessary, the substrate W held by the substrate holder 14 is rotated. Whereupon, due to the potential difference between the seed layer 7 of the substrate W and the anode 16, metal ions in the plating solution 10 receive electrons from the surface of the seed layer 7 of the substrate W, whereby the metal deposits on the surface of the seed layer 7 of the substrate W and forms a copper film (plated film) 6, as shown in FIG. 1B.

The method of the present invention is characterized by the plating solution for use in plating. In particular, the characteristic feature primarily resides in the use of a nitrogen-containing polymer for flattening a surface of a plated film. The nitrogen-containing polymer preferably is one which fattens a surface of a plated film and, is addition, strongly suppresses the electrodeposition promoting effect of a sulfur-containing saturated organic compound which is co-present in the plating solution.

Examples of preferable nitrogen-containing polymers for use in the method of the present invention include a quaternary salt of polydialkylaminoethyl acrylate, polydiallyldimethyl ammonium chloride, polyethleneimine, a quaternary salt of polyvinyl pyridine, polyvinyl amidine, polyallylamine, polyamine sulfonic acid, etc.

The nitrogen-containing polymer is added generally in an amount of about 0.01 to 1000 ppm, preferably about 0.1 to 100 ppm, to the plating solution.

Further, though not essential, another characteristic feature of the present invention resides in adjustment of the concentration of copper ions and the concentration of an organic or inorganic acid in the plating solution. In particular, the copper ion concentration of the plating solution may be adjusted to be not less than 30 g/L, and the organic or inorganic acid concentration not more than 0.4 mol/L.

Though the use of the above-described nitrogen-containing polymer in the plating solution alone is effective in the method of the present invention, a better embedding effect can be produced by additionally carrying out the concentration adjustment for copper ions and an organic or inorganic acid.

The plating solution for use in the method of the present invention may be the same as a common copper-plating solution except for the above-described features. Thus, the present plating solution may contain copper ions, an organic or inorganic acid, chloride ions, a polymeric surfactant for suppressing electrodeposition, a sulfur-containing saturated organic compound for promoting the growth of a plated film, etc.

Any copper compound that is generally used in a plating bath may be employed as a copper ion source. Specific examples may include copper sulfate, copper oxide, copper chloride, copper carbonate, copper pyrophosphate, copper alkanesulfonate such as copper methanesulfonate and copper propanesulfonate, copper alkanolsulfonate such as copper isethionate and copper propanolsulfonate, copper salts of organic acids, such as copper acetate, copper citrate and copper tartrate, and their salts. These copper compounds may be used either singly or in combination of two or more.

The organic or inorganic acid is not particularly limited, and any acid that can dissolve copper is usable. Specific examples of preferable acids include sulfuric acid, alkanesulfonic acids such as methanesulfonic acid and propanesulfonic acid, alkanolsulfonic acids such as isethionic acid and propanolsulfonic acid, and organic acids such as citric acid, tartaric acid and formic acid. These organic or inorganic acids may be used either singly or in combination of two or more.

A copper sulfate plating solution may be exemplified as a preferred plating solution for use in the method of the present invention. A specific copper sulfate plating solution may contain about 200 g/L of copper sulfate pentahydrate, about 0.4 mol/L of sulfuric acid and about 60 ppm of chloride ions.

Examples of the polymeric surfactant for suppressing electrodeposition may include polyethylene glycol (PEG, molecular weight: about 1,000-10,000), polypropylene glycol (molecular weight: about 100-1,000), etc. Such a surfactant may be added in an amount of about 50 to 1,000 ppm to the plating solution. Examples of the sulfur-containing saturated organic compound for promoting the growth of a plated film may include bis(3-sulfopropyl)disulfide (SPS), sodium mercaptopropane-sulfonate (MPS), etc. Such an organic compound may be added in an amount of about 0.1 to 50 ppm to the plating solution.

There is no particular limitation on an apparatus for use in carrying out the method of the present invention, and various apparatuses may be employed. Either a face-up type apparatus, such as the above-described one shown in FIG. 2, in which a substrate is rotated during plating, according to necessity, or a face-down type apparatus may be used, for example. It is also possible to use a plating apparatus which stirs a liquid with a paddle.

The present invention will now be described in more detail in the following Examples which in no way limit the invention.

### EXAMPLE 1

Using a copper sulfate plating solution having the composition described below, plating was carried out onto a surface of a silicon wafer having vias with a diameter of 40 μm and an aspect ratio of 1.5, and having a seed layer (conductive film) which has been formed in the usual manner. As a result, the vias were completely filled with copper. Further, observation of the interior of the via, after cutting the via, revealed no formation of void in the copper.

<Composition of Plating Solution>

| | |
|---|---|
| CuSO₄.5H₂O | 200 g/L |
| H₂SO₄ | 10 g/L |
| Cl | 60 ppm |
| PEG | 200 ppm |

(Molecular Weight: about 3000)

| | |
|---|---|
| SPS | 5 ppm |
| Polyethyleneimine | 1 ppm |

(Molecular Weight: about 10,000)

<Plating Conditions>

| | |
|---|---|
| Liquid temp. | 25° C. |
| Current density | 10 mA/cm² |
| Plating time | 3 hrs |
| Stirring | at 400 rpm (with a stirrer) |

The plating method of the present invention makes it possible to embed copper in vias having an opening size of several tens of μm and an aspect ratio of at least 1.5 without the formation of voids.

Accordingly, the plating method can be advantageously utilized as a means for forming fine interconnects on a substrate.

1. A plating method comprising:
providing a substrate having interconnect recesses, whose surfaces are covered with a conductive layer, formed in a surface of the substrate;
bringing the surface of the substrate into contact with a plating solution containing copper ions, an organic or inorganic acid, chloride ions, a polymeric surfactant for suppressing electrodeposition, a sulfur-containing saturated organic compound for promoting the growth of a plated film, and a nitrogen-containing polymer for flattening a surface of the plated film; and
applying a voltage between the conductive layer and an anode immersed in the plating solution.

2. The plating method according to claim 1, wherein the nitrogen-containing polymer is one which strongly suppresses the electrodeposition promoting effect of the sulfur-containing saturated organic compound.

3. The plating method according to claim 1, wherein the nitrogen-containing polymer is selected from the group consisting of a quaternary salt of polydialkylaminoethyl acrylate, polydiallyldimethyl ammonium chloride, polyethleneimine, a quaternary salt of polyvinyl pyridine, polyvinyl amidine, polyallylamine and polyamine sulfonic acid.

4. The plating method according to claim 1, wherein the copper ion concentration of the plating solution is not less than 30 g/L, and the organic or inorganic acid concentration is not more than 0.4 mol/L.

5. The plating method according to claim 1, wherein the interconnect recesses formed in the surface of the substrate include those having an opening width or size of not less than 1 μm and an aspect ratio of at least 1.

6. The plating method according to claim 1, wherein the substrate is a semiconductor substrate, a printed circuit board or a CSP substrate.

7. A plating solution comprising copper ions, an organic or inorganic acid, chloride ions, a polymeric surfactant for suppressing electrodeposition, a sulfur-containing saturated organic compound for promoting the growth of a plated film, and a nitrogen-containing polymer for flattening a surface of the plated film.

8. The plating solution according to claim 7, wherein the nitrogen-containing polymer is selected from the group consisting of a quaternary salt of polydialkylaminoethyl acrylate, polydiallyldimethyl ammonium chloride, polyethleneimine, a quaternary salt of polyvinyl pyridine, polyvinyl amidine, polyallylamine and polyamine sulfonic acid.

9. The plating solution according to claim 7, wherein the copper ion concentration of the plating solution is not less than 30 g/L, and the organic or inorganic acid concentration is not more than 0.4 mol/L.
